(19) United States
(12) Patent Application Publication
(10) Pub. No.: US 2023/0320182 A1
(43) Pub. Date: Oct. 5, 2023

(54) DISPLAY DEVICE

(71) Applicant: Samsung Display Co., LTD., Yongin-si (KR)

(72) Inventors: Joon Yong PARK, Gunpo-si (KR); Sung Joo KWON, Goyang-si (KR); Hyun Eok SHIN, Gwacheon-si (KR); Dong Min LEE, Anyang-si (KR)

(21) Appl. No.: 18/122,446

(22) Filed: Mar. 16, 2023

(30) Foreign Application Priority Data
Apr. 4, 2022 (KR) 10-2022-0041619

(51) Int. Cl. H10K 59/88

(52) U.S. Cl. CPC H10K 59/88

(57) ABSTRACT

A display device includes a substrate including a pixel area and a dummy area, wherein the pixel area includes a transistor disposed on the substrate, a first electrode electrically connected to the transistor, a second electrode overlapping the first electrode, and a functional layer and an emission layer disposed between the first electrode and the second electrode, and the dummy area includes a first dummy electrode disposed on the substrate, and a dummy insulating layer covering the side of at least part of the first dummy electrode.

This application claims priority to Korean Patent Application No. 10-2022-0041619, filed on Apr. 4, 2022, and all the benefits accruing therefrom under 35 U.S.C. § 119, the content of which in its entirety is herein incorporated by reference.

### BACKGROUND

### (a) Field

The disclosure relates to a display device.

### (b) Description of the Related Art

A display device is a device that displays a screen, and includes a liquid crystal display (“LCD”), a light-emitting diode (“LED”) display, and the like. The display device is used in various electronic devices such as a mobile phone, a navigation device, a digital camera, an electronic book, a portable game machine, and various terminals.

The light-emitting diode display includes two electrodes and an organic emission layer disposed between the two electrodes, and electrons injected from one electrode and holes injected from the other electrode are combined in the organic emission layer such that excitons are formed, and light is emitted by energy generated from the excitons.

The light-emitting diode display includes a plurality of pixels having an organic LED (“OLED”) of a self-light-emitting element, and each pixel includes a plurality of transistors and capacitors to drive the LED. A plurality of thin film transistors includes a switching transistor and a driving transistor.

### SUMMARY

Embodiments are to provide a display device that prevents a connection between a first electrode and a second electrode in a dummy area and prevents a current leakage between adjacent pixel areas.

A display device in an embodiment includes a substrate including a pixel area and a dummy area, wherein the pixel area includes a transistor disposed on the substrate, a first electrode electrically connected to the transistor, a second electrode overlapping the first electrode, and a functional layer and an emission layer disposed between the first electrode and the second electrode, and the dummy area includes a first dummy electrode disposed on the substrate and a dummy insulating layer covering a side of at least part of the first dummy electrode.

In an embodiment, the functional layer and the second electrode may be disconnected in the dummy area.

In an embodiment, the first dummy electrode may include a first first dummy layer, a first second dummy layer, a first third dummy layer, and a first fourth dummy layer.

In an embodiment, the first dummy electrode may have an under-cut shape.

In an embodiment, the first second dummy layer, the first third dummy layer, and the first fourth dummy layer may be further protruded from the first first dummy layer.

In an embodiment, the first first dummy layer may include at least one of indium zinc oxide (“IZO”), indium gallium zinc oxide (“IGZO”), indium tin gallium zinc oxide (“ITGZO”), and indium tin gallium zinc oxide (“ITGO”).

In an embodiment, the first second dummy layer and the first fourth dummy layer may include indium tin oxide (“ITO”), and the first third dummy layer may include silver (Ag).

In an embodiment, the dummy insulating layer may cover a side of the first first dummy layer.

In an embodiment, the functional layer and the second electrode extending from the pixel area may contact the dummy insulating layer.

In an embodiment, the functional layer and the second electrode extending from the pixel area may be insulated from the first dummy electrode.

In an embodiment, the display device may further include a dummy functional layer and a second dummy electrode disposed on the first dummy electrode.

In an embodiment, the dummy functional layer may be separated from the functional layer, and the second dummy electrode may be separated from the second electrode.

In an embodiment, a thickness of the first first dummy layer may be about 500 angstroms to about 1500 angstroms.

A display device in an embodiment includes a substrate including a pixel area and a dummy area, wherein the dummy area is disposed between adjacent pixel areas, and the pixel area includes a transistor disposed on the substrate, a first electrode electrically connected to the transistor, a second electrode overlapping the first electrode, and a functional layer and an emission layer disposed between the first electrode and the second electrode, and the dummy area includes a first dummy electrode disposed on the substrate and including an under-cut, and a dummy insulating layer disposed in the under-cut.

In an embodiment, the first dummy electrode may include a first first dummy layer, a first second dummy layer, a first third dummy layer, and a first fourth dummy layer.

In an embodiment, the first second dummy layer, the first third dummy layer, and the first fourth dummy layer may be further protruded from the first first dummy layer.

In an embodiment, the dummy insulating layer may cover a side of the first first dummy layer.

In an embodiment, the functional layer and the second electrode extending from the pixel area may contact the dummy insulating layer.

In an embodiment, the functional layer and the second electrode extending from the pixel area may be insulated from the first dummy electrode.

In an embodiment, the display device may further include a dummy functional layer and a second dummy electrode disposed on the first dummy electrode, the dummy functional layer may be separated from the functional layer, and the second dummy electrode may be separated from the second electrode.

By embodiments, it is possible to provide a display device that prevents connection of the first electrode and the second electrode in the dummy area between the adjacent pixel areas and prevents current leakage between the adjacent pixel areas.

### BRIEF DESCRIPTION OF THE DRAWINGS

The above and other exemplary embodiments, advantages and features of this disclosure will become more apparent by describing in further detail exemplary embodiments thereof with reference to the accompanying drawings, in which:

FIG. 1 is a schematic exploded perspective view of an embodiment of a display device.

FIG. 2 is cross-sectional view of an embodiment of a display device.

FIG. 3 is a cross-sectional view of an embodiment of a light-emitting element.

FIG. 4 is a cross-sectional view showing a dummy area between adjacent pixel areas.

FIG. 5 to FIG. 8 are cross-sectional views of an embodiment of a manufacturing process of a dummy area, respectively.

FIG. 9 and FIG. 10 are images of an embodiment of a dummy area.

### DETAILED DESCRIPTION

Embodiments of the disclosure will be described more fully hereinafter with reference to the accompanying drawings, in which embodiments of the invention are shown. As those skilled in the art would realize, the described embodiments may be modified in various different ways, all without departing from the spirit or scope of the invention.

Parts that are irrelevant to the description are omitted in the drawings for clear description of the invention, and like reference numerals designate like elements throughout the specification.

Further, the size and thickness of the elements shown in the drawings are arbitrarily illustrated for better understanding and ease of description, and the invention is not necessarily limited thereto. In the drawings, the thickness of layers, films, panels, areas, etc., are exaggerated for clarity. In the drawings, for convenience of description, the thickness of layers, films, panels, areas, etc., are exaggerated.

It will be understood that when an element such as a layer, film, area, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

In addition, unless explicitly described to the contrary, the word “comprise”, and variations such as “comprises” or “comprising”, will be understood to imply the inclusion of stated elements but not the exclusion of any other elements.

Further, throughout the specification, the phrase “in a plan view” means viewing a target portion from the top, and the phrase “in a cross-section” means viewing a cross-section formed by vertically cutting a target portion from the side.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term such as “about” can mean within one or more standard deviations, or within ±30%, 20%, 10%, 5% of the stated value, for example.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

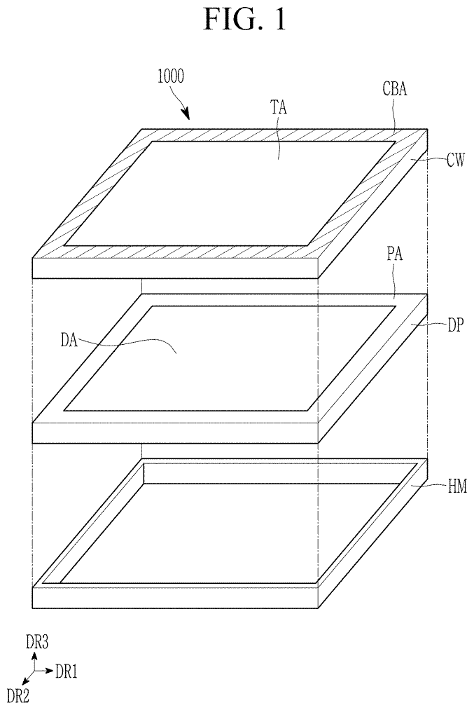

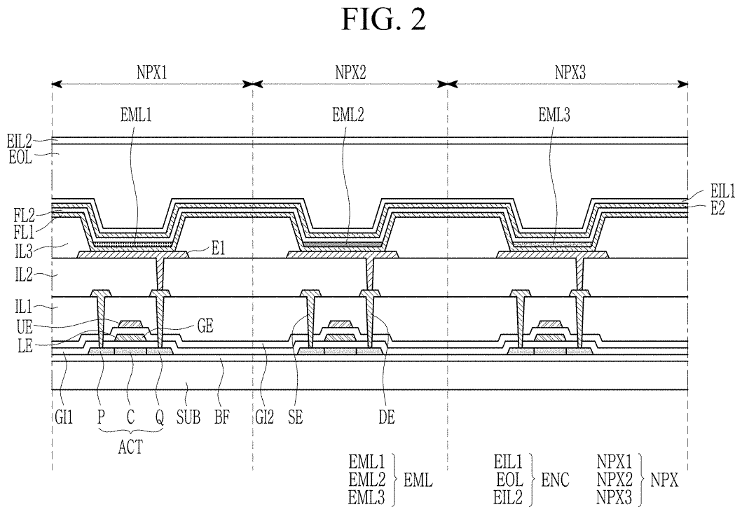

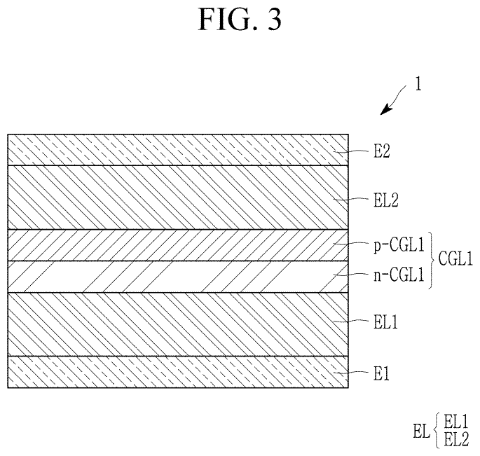

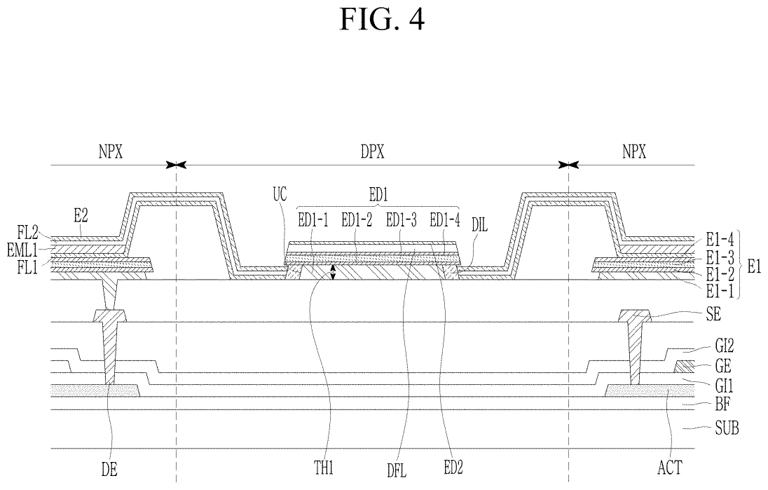

Hereinafter, a display device in an embodiment is described with reference to FIG. 1 to FIG. 4. FIG. 1 is a schematic exploded perspective view of an embodiment of a display device, FIG. 2 is cross-sectional view of an embodiment of a display device, FIG. 3 is a cross-sectional view of an embodiment of a light-emitting element, and FIG. 4 is a cross-sectional view showing a dummy area between adjacent pixel areas.

First, referring to FIG. 1, a display device 1000 in an embodiment may include a cover window CW, a display panel DP, and a housing HM.

The cover window CW may include an insulating panel. In an embodiment, the cover window CW may include glass, plastic, or any combinations thereof, for example.

The front surface of the cover window CW may define the front surface of the display device 1000. The transmissive area TA may be an optically transparent area. In an embodiment, the transmissive area TA may be an area having visible ray transmittance of about 90% or more, for example.

The blocking area CBA may define the shape of the transmissive area TA. The blocking area CBA may be adjacent to the transmissive area TA and may surround the transmissive area TA. The blocking area CBA may be an area having relatively low light transmittance compared to that of the transmissive area TA. The blocking area CBA may include an opaque material that blocks light. The blocking area CBA may have a predetermined color. The blocking area CBA may be defined by the transparent substrate defining the transmissive area TA and a bezel layer provided separately, or by an ink layer formed by inserting or coloring the transparent substrate.

One surface of the display panel DP where the image is displayed is parallel to the surface defined by the first direction DR1 and the second direction DR2. The third direction DR3 indicates a direction that is normal to one surface where the image is displayed, that is, the thickness direction of the display panel DP. The front (or top) surface and back (or bottom) surface of each member are separated in the third direction DR3. However, the directions indicated by the first to third directions DR1, DR2, and DR3 are relative concepts and may be converted to other directions.

The display panel DP may be a flat rigid display panel, but is not limited thereto and may be a flexible display panel. The display panel DP may include an organic light-emitting panel.

The display panel DP includes a display area DA where an image is displayed, and a non-display area PA adjacent to the display area DA. The non-display area PA is an area where no image is displayed. The display area DA may have a quadrangular (e.g., rectangular) shape, for example, and the non-display area PA may have a shape surrounding the display area DA. However, the invention is not limited thereto, and the shapes of the display area DA and the non-display area PA may be relatively designed.

The housing HM provides a predetermined interior space. The display panel DP is disposed (e.g., mounted) inside the housing HM. In addition to the display panel DP, various electronic components, e.g., a power supply unit, a storage device, and a sound input and output module, may be disposed (e.g., mounted) inside the housing HM.

Hereinafter, a pixel area NPX of the display area DA of the display panel DP in an embodiment is described with reference to FIG. 2. The pixel area NPX may include a first pixel area NPX1, a second pixel area NPX2, and a third pixel area NPX3, and a common structure thereof is described below.

Referring to FIG. 2, the display panel DP may include a substrate SUB. The substrate SUB may include an inorganic insulating material such as glass or an organic insulating material such as plastic such as a polyimide (“PI”). The substrate SUB may be single-layered or multi-layered. The substrate SUB may have a structure in which at least one base layer including a polymer resin and at least one inorganic layer are alternately stacked.

The substrate SUB may have a flexibility of various degrees. The substrate SUB may be a rigid substrate or a flexible substrate capable of bending, folding, rolling, etc.

A buffer layer (also referred to as a buffer film) BF may be disposed on the substrate SUB. The buffer film BF blocks impurities from being transferred from the substrate SUB to the upper layer of the buffer film BF, particularly the semiconductor layer ACT, thereby preventing characteristic degradation of the semiconductor layer ACT and reducing stress. The buffer film BF may include an inorganic insulating material such as a silicon nitride or a silicon oxide, or an organic insulating material. In another embodiment, some or all of the buffer film BF may be omitted.

The semiconductor layer ACT is disposed on the buffer layer BF. The semiconductor layer ACT may include at least one of polysilicon and an oxide semiconductor. The semiconductor layer ACT includes a channel area C, a first area P, and a second area Q. The first area P and the second area Q are disposed on opposite sides of the channel area C, respectively. The channel area C may include a semiconductor with a small amount of impurity doped compared to that of the first area P and the second area Q, or without being doped with impurities, and the first area P and the second area Q may include a semiconductor doped with a large amount of the impurity compared to that of the channel area C. The semiconductor layer ACT may include an oxide semiconductor, and in this case, a separate protective layer (not shown) may be added to protect the oxide semiconductor material that is vulnerable to external environments such as a high temperature.

A first gate insulating layer GI1 is disposed on the semiconductor layer ACT.

A gate electrode GE and a lower electrode LE are disposed on the first gate insulating layer GI1. In an embodiment, the gate electrode GE and the lower electrode LE may be unitary. The gate electrode GE and the lower electrode LE may be a single layer or a multilayer in which a metal film including any one of copper (Cu), a copper alloy, aluminum (Al), an aluminum alloy, molybdenum (Mo), a molybdenum alloy, titanium (Ti), and a titanium alloy is stacked. The gate electrode GE may overlap the channel area C of the semiconductor layer ACT.

A second gate insulating layer GI2 may be disposed on the gate electrode GE and the first gate insulating layer GI1. The first gate insulating layer GI1 and the second gate insulating layer GI2 may be a single layer or a multi-layer including at least one among a silicon oxide (SiOₓ), a silicon nitride (SiNₓ), and a silicon oxynitride (SiOₓN_{y}).

An upper electrode UE may be disposed on the second gate insulating layer GI2. The upper electrode UE may form a storage capacitor while overlapping the lower electrode LE.

A first insulating layer IL1 is disposed on the upper electrode UE. The first insulating layer IL1 may be a single layer or a multi-layer including at least one of a silicon oxide (SiOₓ), a silicon nitride (SiNₓ), and a silicon oxynitride (SiOₓN_{y}).

The source electrode SE and the drain electrode DE are disposed on the first insulating layer IL1. The source electrode SE and the drain electrode DE are respectively connected to the first area P and the second area Q of the semiconductor layer ACT through contact holes defined in the insulating layers.

The source electrode SE and the drain electrode DE may include aluminum (Al), silver (Ag), magnesium (Mg), gold (Au), nickel (Ni), chromium (Cr), nickel (Ni), calcium (Ca), molybdenum (Mo), titanium (Ti), tungsten (W), and/or copper (Cu), and may have a single-layer or multi-layer structure including the same.

A second insulating layer IL2 is disposed on the first insulating layer IL′, the source electrode SE, and the drain electrode DE. The second insulating layer IL2 may include an organic insulating material such as a general-purpose polymer such as poly(methyl methacrylate) (“PMMA”) or polystyrene (“PS”), a polymer derivative having a phenolic group, an acryl-based polymer, an imide-based polymer, a polyimide, an acryl-based polymer, and a siloxane-based polymer.

A first electrode E1 may be disposed on the second insulating layer IL2. The first electrode E1 may be connected to the drain electrode DE through the contact hole of the second insulating layer IL2. However, unlike as shown in the drawing, an additional insulating layer may be disposed on the second insulating layer IL2, and a separate metal layer connecting the drain electrode DE and the first electrode E1 may be disposed.

The first electrode E1 may include metals such as silver (Ag), lithium (Li), calcium (Ca), aluminum (Al), magnesium (Mg), or gold (Au), and may also include a transparent conductive oxide (“TCO”) such as an indium tin oxide (“ITO”) or an indium zinc oxide (“IZO”). The first electrode E1 may include a single layer including a metal material or a TCO, or a multi-layer including these. The detailed structure of the first electrode E1 is explained in FIG. 4.

The transistor including the gate electrode GE, the semiconductor layer ACT, the source electrode SE, and the drain electrode DE is connected to the first electrode E1 to supply a current to the light-emitting element.

A partition IL3 is disposed on the second insulating layer IL2 and the first electrode E1. Although not shown, a spacer (not shown) may be disposed on the partition IL3. The partition IL3 overlaps at least a portion of the first electrode E1 and has a partition opening defining a light-emitting area.

The partition IL3 may include an organic insulating material such as a general-purpose polymer such as PMMA or PS, a polymer derivative having a phenolic group, an acryl-based polymer, an imide-based polymer, a polyimide, an acryl-based polymer, or a siloxane-based polymer.

On the partition IL3, a first functional layer FL1, emission layers EML1, EML2, and EML3), and a second functional layer FL2 may be sequentially disposed. The emission layers EML1, EML2, and EML3 may be disposed only within the opening of the partition IL3, and the first functional layer FL1 and the second functional layer FL2 may be disposed while riding on the side and upper surfaces of the partition IL3. The emission layers EML1, EML, and EML3 disposed in each pixel area NPX1, NPX2, and NPX3 may emit different light, or may emit the same light.

The first functional layer FL1 may include a hole injection layer, a hole transport layer, an electron blocking layer, or any combinations thereof. The second functional layer FL2 may include a hole blocking layer, an electron transport layer, an electron injection layer, or any combinations thereof.

The second electrode E2 is disposed on the second functional layer FL2. The second electrode E2 may include a reflective metal such as calcium (Ca), barium (Ba), magnesium (Mg), aluminum (Al), silver (Ag), gold (Au), nickel (Ni), chromium (Cr), lithium (Li), and calcium (Ca), or a TCO such as an ITO and an IZO.

The first electrode E1, the first functional layer FL1, the emission layer EML, the second functional layer FL2, and the second electrode E2 may constitute a light-emitting element. Here, the first electrode E1 may be an anode that is a hole injection electrode, and the second electrode E2 may be a cathode that is an electron injection electrode. However, the disclosure is not limited thereto, and depending on the driving method of the light-emitting display device, the first electrode E1 may become a cathode, and the second electrode E2 may become an anode.

An encapsulating layer ENC is disposed on the second electrode E2. The encapsulating layer ENC may cover and seal the side as well as the top surface of the light-emitting element. Since the light-emitting element is very vulnerable to moisture and oxygen, the encapsulating layer ENC seals the light-emitting element to block the inflow of external moisture and oxygen.

The encapsulating layer ENC may include a plurality of layers, and among them, it may be formed as a composite film including both an inorganic layer and an organic layer, e.g., a triple layer in which a first encapsulation inorganic layer DLL an encapsulation organic layer EOL, and a second encapsulation inorganic layer EIL2 are sequentially formed.

The first encapsulation inorganic layer EIL1 may cover the second electrode E2. The first encapsulation inorganic layer EIL1 may prevent external moisture or oxygen from penetrating into the light-emitting element. In an embodiment, the first encapsulation inorganic layer EIL1 may include a silicon nitride, a silicon oxide, a silicon oxynitride, or any combinations thereof, for example. The first encapsulation inorganic layer EIL1 may be formed through a deposition process.

The encapsulation organic layer EOL may be disposed on the first encapsulation inorganic layer EIL1 and in contact with the first encapsulation inorganic layer EIL1. Curves formed on the upper surface of the first encapsulation inorganic layer EIL1 or particles existing on the first encapsulation inorganic layer EIL1 are covered by the encapsulation organic layer EOL, thereby it is possible to block the influence of the surface state of the upper surface of the first encapsulation inorganic layer EIL1 on the components formed on the encapsulation organic layer EOL. In addition, the encapsulation organic layer EOL may relieve stress between contacting layers. The encapsulation organic layer EOL may include organic materials, and may be formed through a solution process such as spin coating, slit coating, or an inkjet process.

The second encapsulation inorganic layer EIL2 is disposed on the encapsulation organic layer EOL to cover the encapsulation organic layer EOL. The second encapsulation inorganic layer EIL2 may be stably formed on a relatively flat surface compared to the first encapsulation inorganic layer EIL1. The second encapsulation inorganic layer EIL2 encapsulates moisture emitted from the encapsulation organic layer EOL and prevents it from outflowing to the outside. The second encapsulation inorganic layer EIL2 may include a silicon nitride, a silicon oxide, a silicon oxynitride, or any combinations thereof. The second encapsulation inorganic layer EIL2 may be formed through a deposition process.

Although not shown in this specification, a capping layer disposed between the second electrode E2 and the encapsulating layer ENC may be further included. The capping layer may include an organic material. The capping layer protects the second electrode E2 from a subsequent process, e.g., a sputtering process, and improves the light output efficiency of the light-emitting element. The capping layer may have a greater refractive index than that of the first encapsulation inorganic layer EIL1.

Hereinafter, the stacked structure of the light-emitting element in an embodiment is described with reference to FIG. 3. The description of the above-described constituent elements is omitted.

Previously, in FIG. 2, the light-emitting element including the first electrode E1, the first functional layer FL1, the emission layer EML, the second functional layer FL2, and the second electrode E2 has been described. However, the light-emitting device is not limited thereto and may be modified in various forms.

In an embodiment, as shown in FIG. 3, the light-emitting element 1 may include a first electrode E1, a first light-emitting unit ELL a first charge generation layer CGL1, a second light-emitting unit EL2, and a second electrode E2, for example. This specification has described the light-emitting element 1 including two light-emitting units, but is not limited thereto, and the light-emitting element in an embodiment may include one or more light-emitting units.

Each light-emitting unit EL may include an emission layer, and may include at least one of a hole transport area and an electron transport area. The hole transport area may include a hole injection layer, a hole transport layer, an electron blocking layer, or any combinations thereof.

The electron transport area may include a hole blocking layer, an electron transport layer, an electron injection layer, or any combinations thereof. Each light-emitting unit EL may include an emission layer, a hole transport area, and an electron transport area including different materials, or an emission layer, a hole transport area, and an electron transport area including the same material.

The first light-emitting unit EL1 may include a first emission layer that emits light, a first hole transport area that transports holes provided from the first electrode E1 to the first emission layer, and a first electron transport area that transports electrons generated from the first charge generation layer CGL1 to the first emission layer.

The second light-emitting unit EL2 may include a second emission layer for emitting light, a second hole transport area for transporting holes provided from the first charge generation layer CGL1 to the second emission layer, and a second electron transport area for transporting electrons to the second emission layer. In an embodiment, the first charge generation layer CGL1 may include a first positive sub-charge generation layer p-CGL1 and a first negative sub-charge generation layer n-CGL1, but the disclosure is not limited thereto.

The emission layers included in each of the first light-emitting unit EL1 and the second light-emitting unit EL2 may emit light of different colors or may emit light of the same color.

The emission layer may include at least one selected from an organic compound and a semiconductor compound, but is not limited thereto. When the emission layer includes an organic compound, the light-emitting element may be also referred to as an organic light-emitting element.

Hereinafter, the dummy area is described with reference to FIG. 4.

The display area DA in an embodiment may include a plurality of pixel areas NPX, and a dummy area DPX disposed between the adjacent pixel areas NPX. The stacked structure of each pixel area NPX disposed in the display area DA is the same as that described through FIG. 2 above, and hereinafter the dummy area DPX is described in detail.

The dummy area DPX may include the buffer layer BF, the first gate insulating layer GI1, the second gate insulating layer GI2, the first insulating layer ILL and the second insulating layer IL2, which are disposed on the substrate SUB and connected to the pixel area NPX. The stacked structure of the dummy area DPX is not limited thereto, and may vary depending on the stacked structure of the pixel area NPX.

A first dummy electrode ED1 may be disposed on the second insulating layer IL2. The first dummy electrode ED1 may include a first first dummy layer ED1-1, a first second dummy layer ED1-2, a first third dummy layer ED1-3, and a first fourth dummy layer ED1-4, which are sequentially stacked.

The first first dummy layer ED1-1 includes the same material as that of the first first layer E1-1 disposed in the pixel area NPX, and may be formed in the same process. The first second dummy layer ED1-2 includes the same material as that of the first second layer E1-2 disposed in the pixel area NPX, and may be formed in the same process. The first third dummy layer ED1-3 includes the same material as that of the first third layer E1-3 disposed in the pixel area NPX, and may be formed in the same process. The first fourth dummy layer ED1-4 includes the same material as that of the first fourth layer E1-4 disposed in the pixel area NPX, and may be formed in the same process. In an embodiment, the first first dummy layer ED1-1 may include any one of IZO, indium gallium zinc oxide (“IGZO”), indium tin gallium zinc oxide (“ITGZO”), and indium tin gallium zinc oxide (“ITGO”), the first second dummy layer ED1-2 and the first fourth dummy layer ED1-4 may include a TCO such as an ITO or an IZO, and the first third dummy layer ED1-3 may include a metal such as silver (Ag), lithium (Li), calcium (Ca), aluminum (Al), magnesium (Mg), or gold (Au), for example. The thickness Th1 of the first first dummy layer ED1-1 in an embodiment may be about 500 angstroms to about 1500 angstroms in a thickness direction (e.g., vertical direction in FIG. 4).

The first dummy electrode ED1 in an embodiment may have an under-cut shape in which an under-cut UC is defined. In an embodiment, the ends of the first second dummy layer ED1-2, the first third dummy layer ED1-3, and the first fourth dummy layer ED1-4 may be protruded past the end of the first first dummy layer ED1-1, for example. The end of the first first dummy layer ED1-1 may be disposed inside the ends of the first second dummy layer ED1-2, the first third dummy layer ED1-3, and the first fourth dummy layer ED1-4. The etching speed of the first first dummy layer ED1-1) in an embodiment is faster than the etching speed of the first second dummy layer ED1-2, the first third dummy layer ED1-3, and the first fourth dummy layer ED1-4, and the undercut may be defined in the first first dummy layer ED1-1.

The dummy insulating layer DIL may be disposed on the side of the first first dummy layer ED1-1. The dummy insulating layer DIL includes the same material as that of the partition IL3 disposed in the pixel area NPX in the embodiment, and may be formed in the same process.

The dummy insulating layer DIL may cover at least a part of the side surface of the first dummy electrode ED1, and for example, it may completely cover the side surface of the first first dummy layer ED1-1. The dummy insulating layer DIL may be formed to fill the under-cut UC defined in the first first dummy layer ED1-1.

A dummy functional layer DFL and a second dummy electrode ED2 may be disposed on the first dummy electrode ED1. Although the dummy functional layer DFL is illustrated in the form of a single layer, it may have a double layer structure including the first functional layer FL1 and the second functional layer FL2 disposed in the pixel area NPX. The dummy functional layer DFL may include the same material as that of the first functional layer FL1 and the second functional layer FL2, and may be formed in the same process. The second dummy electrode ED2 includes the same material as that of the second electrode E2 disposed in the pixel area NPX, and may be formed in the same process.

The dummy functional layer DFL may have a shape that is disconnected from the first functional layer FL1 and the second functional layer FL2. The dummy functional layer DFL, and the first functional layer FL1 and the second functional layer FL2, may be spaced apart by the under-cut UC of the first dummy electrode ED1.

Similarly, the second dummy electrode ED2 may have a shape that is disconnected from the second electrode E2. The second dummy electrode ED2 and the second electrode E2 may be spaced apart by the under-cut UC of the first dummy electrode ED1.

The ends of the first functional layer FL1, the second functional layer FL2, and the second electrode E2 extending from the pixel area NPX to the dummy area DPX may contact the dummy insulating layer DIL. In an alternative embodiment, in an embodiment, the ends of the first functional layer FL1, the second functional layer FL2, and the second electrode E2 extending from the pixel area NPX to the dummy area DPX may be disposed adjacent to the dummy insulating layer DIL and spaced by a predetermined distance from the dummy insulating layer DIL.

The ends of the first functional layer FL1, the second functional layer FL2, and the second electrode E2 extending from the pixel area NPX to the dummy area DPX may be insulated from the first dummy electrode ED1, the dummy functional layer DFL, and the second dummy electrode ED2 through the dummy insulating layer DIL. Accordingly, a current leakage between adjacent pixel areas may be prevented. By preventing the current leakage, color mixing occurring in a low gray may be reduced.

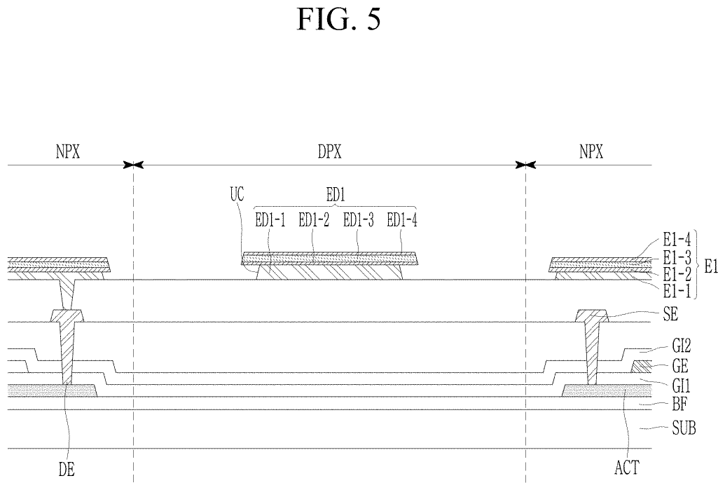

Hereinafter, a manufacturing method of a display device in an embodiment is described with reference to FIG. 5 to FIG. 8

FIG. 5 to FIG. 8 are cross-sectional views according to a manufacturing process of a dummy area in an embodiment, respectively. The description of the same constituent elements as the above-described constituent elements is omitted.

First, referring to FIG. 5, in an embodiment, on the second insulating layer IL2, the first electrode E1 overlapping the pixel area NPX and the first dummy electrode ED1 overlapping the dummy area DPX are formed. In this case, each of the formed first electrode E1 and first dummy electrode ED1 may have an under-cut shape in which an under-cut UC is defined.

The first electrode E1 may include a first first layer E1-1, a first second layer E1-2, a first third layer E1-3, and a first fourth layer E1-4. The first dummy electrode ED1 may include the first first dummy layer ED1-1, the first second dummy layer ED1-2, the first third dummy layer ED1-3, and the first fourth dummy layer ED1-4.

The first first layer E1-1 may include a material having a faster etching speed than that of the first second layer E1-2, the first third layer E1-3, and the first fourth layer E1-4, and a greater amount of the first first layer E1-1 may be etched than that of the first second layer E1-2, the first third layer E1-3, and the first fourth layer E1-4 to define an under-cut UC. The first first dummy layer ED1-1 may include a material with a faster etching speed than that of the first second dummy layer ED1-2, the first third dummy layer ED1-3, and the first fourth dummy layer ED1-4. The first first dummy layer ED1-1 may be etched a larger amount than that of the first second dummy layer ED1-2, the first third dummy layer ED1-3, and the first fourth dummy layer ED1-4 to define an under-cut UC.

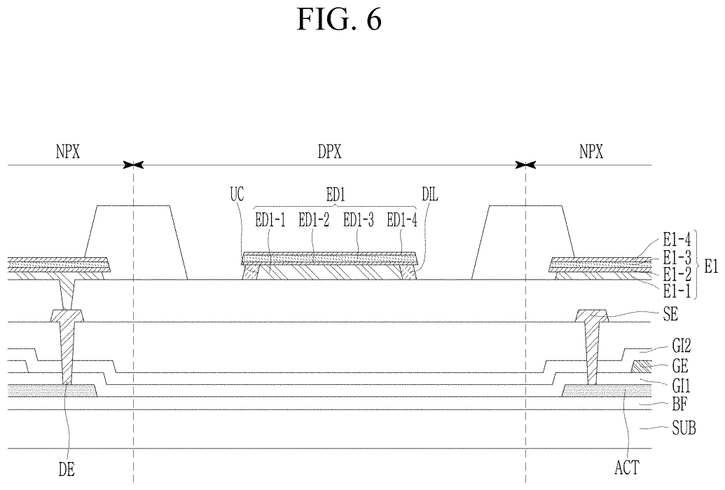

Next, as shown in FIG. 6, the partition IL3 spanning the pixel area NPX and the dummy area DPX, and the dummy insulating layer DIL formed in the dummy area DPX may be included.

The partition IL3 and the dummy insulating layer DIL may be formed through an etching process after coating an organic insulating material on the entire surface of the substrate SUB. The partition IL3 may be formed using a photoresist pattern. The dummy insulating layer DIL may be formed by adjusting an exposure amount and an exposure time during the etching process.

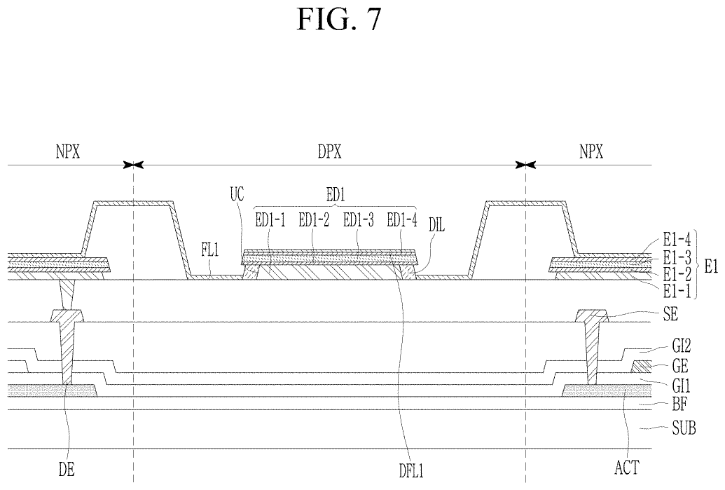

Next, as shown in FIG. 7, a first functional layer FL1 may be formed for the entire surface of the substrate SUB. The first functional layer FL1 may be continuously formed in the pixel area NPX, and may have a shape that is disconnected by the under-cut UC in the dummy area DPX. A first functional layer FL1 that is the same as the first dummy functional layer DFL1 may be formed on the first dummy electrode ED1.

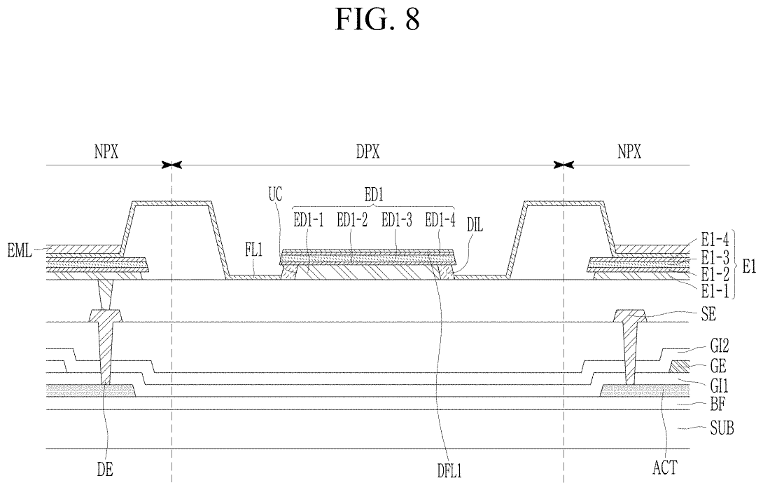

Then, as shown in FIG. 8, an emission layer EML may be formed in each pixel area NPX. The emission layer may not be formed in the dummy area DPX.

After that, by forming a second functional layer FL2 and a second electrode E2 on the entire surface of the substrate SUB, the same structure as that of FIG. 4 may be provided. The second functional layer FL2 and the second electrode E2 may be continuously formed in the pixel area NPX, and may have a disconnected shape due to the under-cut UC in the dummy area DPX. A second dummy functional layer and a second dummy electrode ED2 including the same material as that of the second functional layer FL2 may be formed on the first dummy electrode ED1. In FIG. 4, the first dummy functional layer and the second dummy functional layer are expressed as one dummy functional layer DFL, but the invention is not limited thereto, and may include a first dummy functional layer and a second dummy functional layer formed as separate layers.

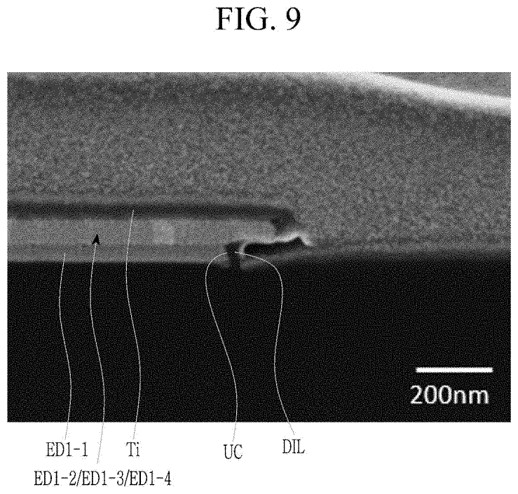

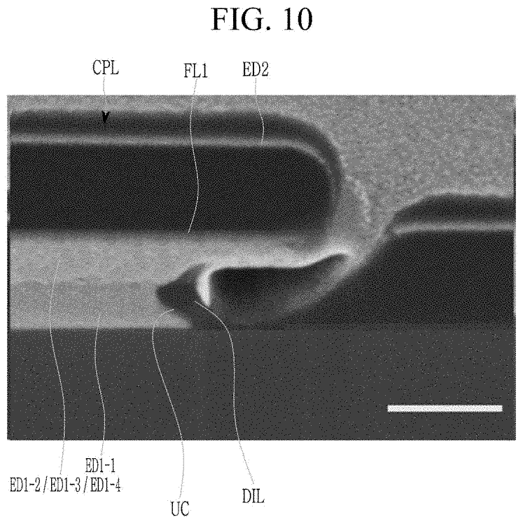

Hereinafter, a partial area of the display panel in an embodiment is described with reference to FIG. 9 and FIG. 10. FIG. 9 and FIG. 10 are images of a dummy area.

First referring to FIG. 9, the first dummy electrode in an embodiment may have a quadruple layer structure stacked in the order of IZO/ITO/Ag/ITO. At this time, it was confirmed that the under-cut UC is defined in the first first dummy layer ED1-1 including IZO. Then, a dummy insulating layer DIL was formed. It was confirmed that the dummy insulating layer DIL is formed in the under-cut UC of the first first dummy layer ED1-1. After that, a titanium layer (Ti) was deposited on the entire surface of the substrate. It was confirmed that the titanium film (Ti) has a disconnected shape in the under-cut UC and is completely insulated from the first dummy electrode by the dummy insulating layer DIL.

Also, referring to FIG. 10, the first dummy electrode in an embodiment may have a quadruple layer structure stacked in the order of IZO/ITO/Ag/ITO. At this time, it was confirmed that the under-cut UC is defined in the first first dummy layer ED1-1 including IZO. Then, a dummy insulating layer DIL was formed. It was confirmed that the dummy insulating layer DIL is formed in the under-cut UC of the first first dummy layer ED1-1. Next, a first functional layer FL1, a second dummy electrode ED2, and a capping layer CPL were deposited on the entire surface of the substrate. It was confirmed that the first functional layer FL1 and the second dummy electrode ED2 have a disconnected shape in the under-cut UC, and were also completely insulated from the first dummy electrode ED1 by the dummy insulating layer DIL.

As described above, the ends of the first functional layer FL1, the second functional layer FL2, and the second electrode E2 extending from the pixel area NPX to the dummy area DPX have the disconnected shape by the undercut, and may be insulated from the first dummy electrode ED1, the dummy functional layer DFL, and the second dummy electrode ED2 through the dummy insulating layer DIL. Through this structure of the dummy area, the current leakage between the adjacent pixel areas may be prevented. By preventing the current leakage, color mixing occurring in a low gray may be reduced.

While this invention has been described in connection with what is presently considered to be practical embodiments, it is to be understood that the invention is not limited to the disclosed embodiments. On the contrary, it is intended to cover various modifications and equivalent arrangements included within the spirit and scope of the appended claims.

What is claimed is:

1. A display device comprising
a substrate including:
a pixel area including:
a transistor disposed on the substrate;
a first electrode electrically connected to the transistor;
a second electrode overlapping the first electrode; and
a functional layer and an emission layer disposed between the first electrode and the second electrode; and
a dummy area including:
a first dummy electrode disposed on the substrate, and
a dummy insulating layer covering a side of at least part of the first dummy electrode.

2. The display device of claim 1, wherein
the functional layer and the second electrode are disconnected in the dummy area.

3. The display device of claim 1, wherein
the first dummy electrode includes a first first dummy layer, a first second dummy layer, a first third dummy layer, and a first fourth dummy layer.

4. The display device of claim 3, wherein
the first dummy electrode has an under-cut shape.

5. The display device of claim 3, wherein
the first second dummy layer, the first third dummy layer, and the first fourth dummy layer are further protruded than the first first dummy layer.

6. The display device of claim 3, wherein
the first first dummy layer includes at least one of indium zinc oxide, indium gallium zinc oxide, indium tin gallium zinc oxide, and indium tin gallium zinc oxide.

7. The display device of claim 6, wherein
the first second dummy layer and the first fourth dummy layer include indium tin oxide, and the first third dummy layer includes silver.

8. The display device of claim 3, wherein
the dummy insulating layer covers a side of the first first dummy layer.

9. The display device of claim 8, wherein
the functional layer and the second electrode extending from the pixel area contact the dummy insulating layer.

10. The display device of claim 9, wherein
the functional layer and the second electrode extending from the pixel area are insulated from the first dummy electrode.

11. The display device of claim 1, further comprising a dummy functional layer and a second dummy electrode disposed on the first dummy electrode.

12. The display device of claim 11, wherein
the dummy functional layer is separated from the functional layer, and
the second dummy electrode is separated from the second electrode.

13. The display device of claim 3, wherein
a thickness of the first first dummy layer is about 500 angstroms to about 1500 angstroms.

14. A display device comprising
a substrate including:
a pixel area including:
a transistor disposed on the substrate;
a first electrode electrically connected to the transistor;
a second electrode overlapping the first electrode; and
a functional layer and an emission layer disposed between the first electrode and the second electrode; and
a dummy area disposed between adjacent pixel areas and including:
a first dummy electrode disposed on the substrate and having an under-cut; and
a dummy insulating layer disposed in the under-cut.

15. The display device of claim 14, wherein
the first dummy electrode includes a first first dummy layer, a first second dummy layer, a first third dummy layer, and a first fourth dummy layer.

16. The display device of claim 15, wherein
the first second dummy layer, the first third dummy layer, and the first fourth dummy layer are further protruded than the first first dummy layer.

17. The display device of claim 15, wherein
the dummy insulating layer covers a side of the first first dummy layer.

18. The display device of claim 17, wherein
the functional layer and the second electrode extending from the pixel area contact the dummy insulating layer.

19. The display device of claim 17, wherein
the functional layer and the second electrode extending from the pixel area are insulated from the first dummy electrode.

20. The display device of claim 14, further comprising a dummy functional layer and a second dummy electrode disposed on the first dummy electrode,
wherein the dummy functional layer is separated from the functional layer, and the second dummy electrode is separated from the second electrode.
